(19) United States
(12) Patent Application Publication
(10) Pub. No.: US 2015/0294975 A1
(43) Pub. Date: Oct. 15, 2015

(54) SEMICONDUCTOR DEVICE AND METHOD OF MANUFACTURING THE SAME

(71) Applicant: PS5 LUXCO S.A.R.L., Luxembourg (LU)

(72) Inventor: Shinichi Nakata, Tokyo (JP)

(21) Appl. No.: 14/442,811

(22) PCT Filed: Nov. 11, 2013
(86) PCT No.: PCT/JP2013/080387

§ 371 Date: May 14, 2015

(30) Foreign Application Priority Data
Nov. 14, 2012 (JP) 2012-250106

(51) Int. Cl. H01L 27/108; H01L 29/423; H01L 21/3213; H01L 29/51; H01L 21/02; H01L 21/768

(52) U.S. Cl. CPC H01L 27/10891; H01L 27/10885; H01L 27/10876; H01L 27/1085; H01L 27/10823; H01L 21/02247; H01L 21/76877; H01L 21/76871; H01L 21/76843; H01L 21/0223; H01L 21/32133; H01L 21/0217; H01L 21/0214; H01L 21/02178; H01L 21/0228; H01L 29/511; H01L 29/517; H01L 29/518; H01L 29/4236; H01L 21/02252; H01L 21/02255

(57) ABSTRACT

This semiconductor device comprises: a trench that is provided in a semiconductor substrate; an insulating film that covers the inner surface of the trench; and a buried wiring line that fills up the lower part within the trench and is in contact with the insulating film. A barrier insulating film is arranged at least at the interface between the insulating film and the buried wiring line.

### TECHNICAL FIELD

The present invention relates to a semiconductor device and a method for manufacturing the same, and more specifically relates to a semiconductor device containing transistors provided with an embedded metal gate electrode, and a method for manufacturing the same.

### BACKGROUND ART

In semiconductor devices such as DRAMs (Dynamic Random Access Memory), miniaturization has occurred in conjunction with the adoption of memory arrays comprising transistors having an embedded word line construction, in which the active regions of memory cells are formed in a line pattern, trenches extending in a direction which intersects the active regions are formed in a substrate, and word lines (gate electrodes) are embedded in the trenches (patent literature article 1). If F is the minimum processing dimension, then in F30 and F25 generation DRAMs the trenches are formed to a width of approximately 30 nm and 25 nm respectively.

The embedded word lines are formed using a method in which a hard mask pattern is formed on the surface of a semiconductor (silicon) substrate, after which trench structures are formed by dry etching. A silicon dioxide film which will serve as a gate insulating film is formed by thermal oxidation on the semiconductor (silicon) substrate surface that is exposed in the trenches, after which a barrier film is formed using titanium nitride (TiN) or the like, and low-resistance tungsten (W), which will serve as a main electrical conductor, is formed. CVD (Chemical Vapor Deposition), which is satisfactory for step coverage, is used to deposit the TiN and W. The deposited TiN film and W film are processed by etching back in such a way that the surfaces thereof are lower than the semiconductor substrate surface, said surfaces preferably being at a depth that is the same as the bottom surface of an impurity-diffused layer formed in the semiconductor substrate. A silicon dioxide film or the like is then deposited onto the surface of the TiN film and the W film that have receded, and this is planarized by CMP (Chemical Mechanical Polishing) or the like to form a cap insulating film, thereby completing the embedded word line comprising the TiN film and the W film.

### PATENT LITERATURE

Patent literature article 1: Japanese Patent Kokai 2012-19035

### SUMMARY OF THE INVENTION

### Problems to be Resolved by the Invention

As discussed in the background art section, CVD is used to embed a W film in a stepped structure such as the trench of an embedded word line. If the W film is formed using CVD, two-step deposition, comprising a seed-layer (W core) forming step and a bulk W deposition step, is employed. In the seed layer forming step, WF₆ is used as the feed gas, and SiH₄ or B₂H₆ is used as the reductive gas. Further, in the bulk W deposition step which requires rapid deposition, WF₆ is used as the feed gas and H₂ is used as the reductive gas. Reaction by-products such as F and HF, which may damage the silicon substrate or the gate insulating film, are generated when these films are being deposited.

Meanwhile, if the width of the trench structure becomes smaller as a result of miniaturization of the semiconductor device, the space in which to embed the bulk W film becomes narrower, and there is a risk that it will cease to exist. In order to maintain a space in which to form the bulk W film, it is conceivable to employ methods in which the thickness of the barrier film or the seed layer is reduced. However, according to investigations conducted by the inventors, if the thickness of the barrier film is reduced to less than 5 nm, problems arise in that there is a degradation of the transistor characteristics, and reliability cannot be ensured. The cause of this is thought to be that reducing the thickness of the barrier film results in a deterioration in the barrier properties with respect to diffusion into the silicon dioxide film of reaction by-products such as fluorine (F) and hydrogen (H), generated when the W film is formed by CVD. Further, the W seed layer itself also functions as a barrier film when the bulk W film is being formed, and it has been confirmed that if the thickness of the seed layer is reduced to less than 5 nm, then degradation of the transistor characteristics appears. The thickness of the W seed layer is not an issue if the barrier TiN film can be formed as a thick film having a thickness of 10 nm or more, but if the thickness of the barrier TiN film is reduced to 5 nm then the barrier properties of the seed layer itself are critical. In order to avoid degradation of the transistor, both of the films must be formed to a thickness of at least 5 nm.

### Means of Overcoming the Problems

According to one mode of embodiment of the present invention, there is provided a semiconductor device characterized in that it is provided with: a trench provided in a semiconductor substrate; an insulating film covering an inner surface of the trench; and an embedded wiring line which fills a lower portion within the trench and which is in contact with the insulating film, and in that a barrier insulating film is disposed at an interface between the insulating film and the embedded wiring line.

Further, according to another mode of embodiment of the present invention, there is provided a method of manufacturing a semiconductor device, characterized in that it is provided with: a step of forming a trench in a semiconductor substrate; a step of forming a first insulating film on an inner surface of the trench; a step of forming a barrier insulating film at least on the first insulating film; a step of forming a barrier metal film over the entire surface including the barrier insulating film; a step of forming a seed layer on the barrier metal film; a step of filling the trench by forming a metal film on the seed layer; and a step of etching back the metal film, the seed layer and the barrier metal film to form an embedded wiring line filling a lower portion of the trench.

### Advantages of the Invention

According to one mode of embodiment of the present invention, the configuration is such that a barrier insulating film is disposed at a boundary between an insulating film provided on the inner surface of a trench and an embedded wiring line provided on the insulating film. The barrier insulating film differs from a metal barrier film having grain boundaries in that it has an amorphous configuration, and therefore barrier effects can be increased. Therefore even if the thickness of the barrier metal film or the seed layer which forms the embedded wiring line is reduced, it is possible to avoid the problem whereby reaction by-products generated when the metal film is formed diffuse into the insulating film, causing the reliability of the insulating film to deteriorate. It is thus possible to provide a semiconductor device comprising transistors having satisfactory characteristics, while at the same time preventing an increase in the resistance of the embedded wiring lines, even if the semiconductor device is miniaturized.

### BRIEF EXPLANATION OF THE DRAWINGS

FIG. 1 is a plan view illustrating the layout of constituent elements in a semiconductor device according to embodiment 1 of the present invention.

FIG. 1A is a cross-sectional view through the line A-A′ in FIG. 1.

FIG. 1B is a cross-sectional view through the line B-B′ in FIG. 1.

FIG. 1C is a cross-sectional view through the line C-C′ in FIG. 1.

FIG. 1D is a cross-sectional view through the line D-D′ in FIG. 1.

FIG. 1E is a perspective view used to describe the internal structure of the semiconductor device in FIG. 1.

FIG. 2 is a plan view used to describe a step in the manufacture of the semiconductor device according to embodiment 2 of the present invention.

FIG. 2A is a cross-sectional view through the line A-A′ in FIG. 2.

FIG. 2B is a cross-sectional view through the line B-B′ in FIG. 2.

FIG. 3 is a plan view used to describe the step following the step illustrated in FIG. 2.

FIG. 3A is a cross-sectional view through the line A-A′ in FIG. 3.

FIG. 3B is a cross-sectional view through the line B-B′ in FIG. 3.

FIG. 4 is a plan view used to describe the step following the step illustrated in FIG. 3.

FIG. 4A is a cross-sectional view through the line A-A′ in FIG. 4.

FIG. 4B is a cross-sectional view through the line B-B′ in FIG. 4.

FIG. 4D is a cross-sectional view through the line D-D′ in FIG. 4.

FIG. 5 is a plan view used to describe the step following the step illustrated in FIG. 4.

FIG. 5A is a cross-sectional view through the line A-A′ in FIG. 5.

FIG. 5B is a cross-sectional view through the line B-B′ in FIG. 5.

FIG. 5D is a cross-sectional view through the line D-D′ in FIG. 5.

FIG. 5G is a cross-sectional view illustrating another example of the shape of a saddle fin.

FIG. 5H is a cross-sectional view illustrating yet another example of the shape of a saddle fin.

FIG. 6B is a drawing used to describe the step following the step illustrated in FIG. 5, being a cross-sectional view in a position corresponding to the line B-B′ in FIG. 5.

FIG. 6D is a drawing used to describe the step following the step illustrated in FIG. 5, being a cross-sectional view in a position corresponding to the line D-D′ in FIG. 5.

FIG. 7B is a drawing used to describe the step following the step illustrated in FIG. 6B and FIG. 6D, being a cross-sectional view in a position corresponding to the line B-B′ in FIG. 5.

FIG. 7D is a drawing used to describe the step following the step illustrated in FIG. 6B and FIG. 6D, being a cross-sectional view in a position corresponding to the line D-D′ in FIG. 5.

FIG. 8B is a drawing used to describe the step following the step illustrated in FIG. 7B and FIG. 7D, being a cross-sectional view in a position corresponding to the line B-B′ in FIG. 5.

FIG. 8D is a drawing used to describe the step following the step illustrated in FIG. 7B and FIG. 7D, being a cross-sectional view in a position corresponding to the line D-D′ in FIG. 5.

FIG. 9D is a cross-sectional view in a position corresponding to the line D-D′ in FIG. 5, used to describe the structure of a comparative example.

FIG. 10B is a drawing used to describe the step following the step illustrated in FIG. 8B and FIG. 8D, being a cross-sectional view in a position corresponding to the line B-B′ in FIG. 5.

FIG. 10D is a drawing used to describe the step following the step illustrated in FIG. 7B and FIG. 7D, being a cross-sectional view in a position corresponding to the line D-D′ in FIG. 5.

FIG. 11A is a drawing used to describe the step following the step illustrated in FIG. 10B and FIG. 10D, being a cross-sectional view in a position corresponding to the line A-A′ in FIG. 5.

FIG. 11B is a drawing used to describe the step following the step illustrated in FIG. 10B and FIG. 10D, being a cross-sectional view in a position corresponding to the line B-B′ in FIG. 5.

FIG. 11D is a drawing used to describe the step following the step illustrated in FIG. 10B and FIG. 10D, being a cross-sectional view in a position corresponding to the line D-D′ in FIG. 5.

FIG. 12A is a drawing used to describe the step following the step illustrated in FIG. 11A, FIG. 11B and FIG. 11D, being a cross-sectional view in a position corresponding to the line A-A′ in FIG. 5.

FIG. 13A is a drawing used to describe the step following the step illustrated in FIG. 12A, being a cross-sectional view in a position corresponding to the line A-A′ in FIG. 5.

FIG. 14A is a drawing used to describe the step following the step illustrated in FIG. 13A, being a cross-sectional view in a position corresponding to the line A-A′ in FIG. 5.

FIG. 15A is a drawing used to describe the step following the step illustrated in FIG. 12A, being a cross-sectional view in a position corresponding to the line A-A′ in FIG. 5.

FIG. 16D is a drawing used to describe the configuration of a semiconductor device according to embodiment 3 of the present invention, being a cross-sectional view in a position corresponding to the line D-D′ in FIG. 5.

### MODES OF EMBODYING THE INVENTION

With regard to preferred exemplary embodiments of the present invention, a semiconductor device forming a DRAM (Dynamic Random Access Memory) will now be described by way of example with reference to the drawings. However, the present invention is not limited only to these exemplary embodiments.

### Embodiment 1

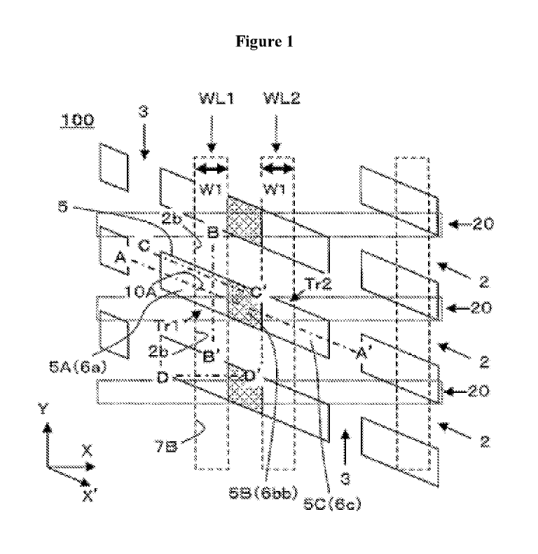

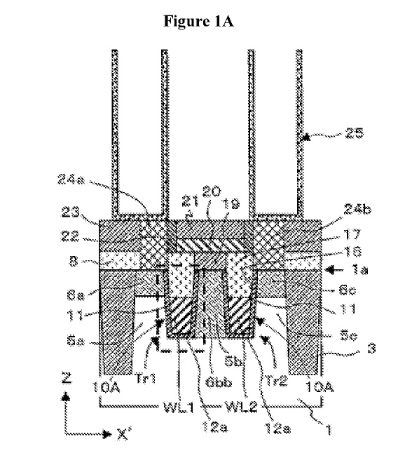

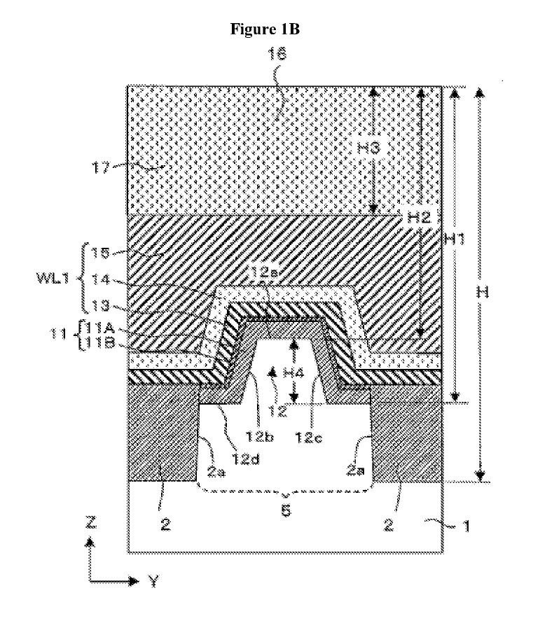

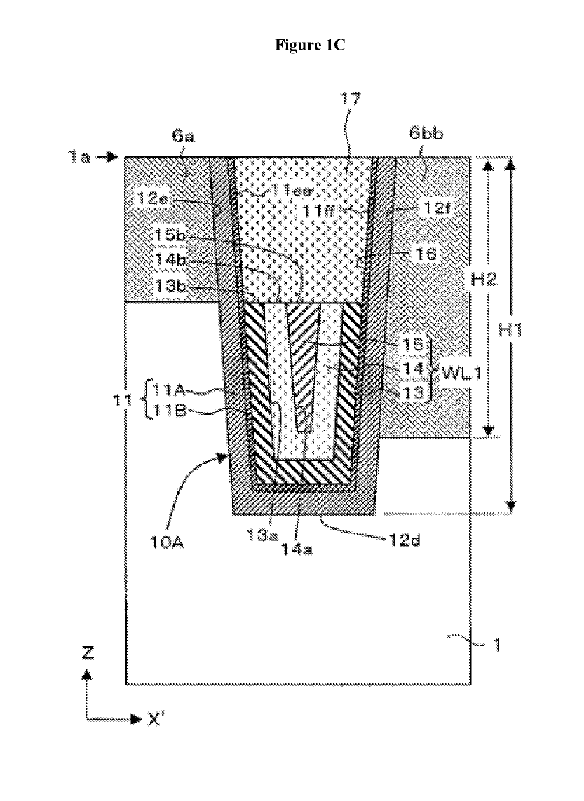

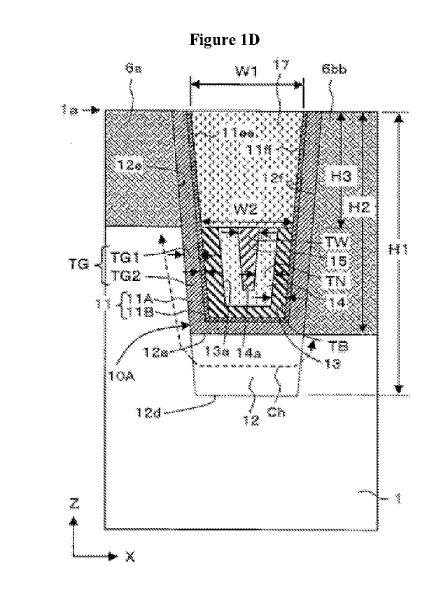

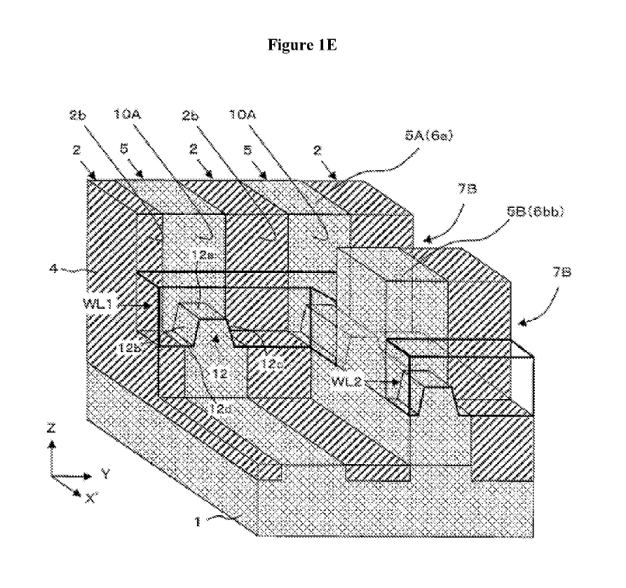

The configuration of the semiconductor device in this embodiment will first be described with reference to FIG. 1, FIG. 1A, FIG. 1B, FIG. 1C, FIG. 1D and FIG. 1E. FIG. 1 is a plan view illustrating the planar layout of the constituent elements of the semiconductor device, FIG. 1A is a cross-sectional view through the line A-A′ in FIG. 1, FIG. 1B is a cross-sectional view through the line B-B′, FIG. 1C is a cross-sectional view through the line C-C′, and FIG. 1D is a cross-sectional view through the line D-D′. Further, FIG. 1E is a cut-away perspective view of the semiconductor device, used to describe the internal structure of the semiconductor device according to this mode of embodiment. It should be noted that the dimensions of the parts in the drawings are not necessarily proportional to the dimensions of the actual parts. Further, the scale of the drawings is not necessarily common. Further, some parts are omitted from each drawing for convenience of description, and in some cases the drawings are not mutually consistent.

The disposition of the main parts of the semiconductor device in this embodiment will first be described with reference to the plan view in FIG. 1. FIG. 1 illustrates the layout of part of a memory cell region 100 disposed on a semiconductor substrate. The structure of capacitor parts is omitted from FIG. 1. The memory cell region 100 is defined on the semiconductor substrate. The semiconductor substrate is, for example, a p-type silicon single-crystal substrate, but is not limited to this.

In the memory cell region 100, first element isolation regions 2 extending in a straight line in the X′-direction (first direction) which is inclined from the X-direction (third direction), and active regions 5 extending in a straight line in the X′-direction, adjacent to the first element isolation regions 2, are disposed repeatedly in the Y-direction (second direction) with an equal pitch spacing. The Y-direction is a direction intersecting the X-direction and the X′-direction.

Each active region 5 is electrically isolated by means of first element isolation regions 2 from other active regions 5 adjacent thereto in the Y-direction. Further, each active region 5 is electrically isolated by means of second element isolation regions 3, extending in the Y-direction, from other active regions 5 adjacent thereto in the X′-direction. In other words, each active region 5 is configured as an island-shaped active region.

The first element isolation regions 2 and the second element isolation regions 3 are formed by a known STI (Shallow Trench Isolation) method, and are configured using an element isolation insulating film comprising a silicon dioxide film which fills grooves formed in the semiconductor substrate. The depth of the first element isolation regions 2 and the second element isolation regions 3 is 250 nm, for example.

Two embedded wiring lines WL1 and WL2 extending in a straight line in the Y-direction are disposed straddling a plurality of element isolation regions 2 and a plurality of active regions 5. The embedded wiring lines WL1 and WL2 are embedded in lower portions of word trenches (trenches) 7B extending in a straight line in the Y-direction and straddling the first element isolation regions 2 and the active regions 5.

Each word trench 7B is formed by alternately disposing first trenches 2b provided in the locations of the first element isolation regions 2, and second trenches 10A provided in the locations of the active regions 5.

The embedded wiring lines WL1 and WL2 form word lines of the DRAM, and also serve as the gate electrodes of transistors, discussed hereinafter. In the following description, the embedded wiring lines WL1 and WL2 are referred to as word lines.

One second element isolation region 3 and two word lines WL1 and WL2 form one set, and these sets are disposed repeatedly in the X-direction. In FIG. 1, two word lines WL1 and WL2 are disposed with a uniform spacing between two adjacent second element isolation regions 3. In other words, the second element isolation regions 3 and word lines WL1 and WL2 are each disposed with the same width and the same spacing.

By means of the abovementioned arrangement, the island-shaped active regions 5 are demarcated into one capacitor contact region (first contact region) 5A adjacent to one second element isolation region 3 and the word line WL1, a bit line contact region (second contact region) 5B adjacent to the word line WL1 and the word line WL2, and another capacitor contact region (third contact region) 5C adjacent to the word line WL2 and another second element isolation region 3.

One of the capacitor contact regions 5A, the word line WL1 and the bit line contact region 5B form one transistor Tr1. Further, the bit line contact region 5B, the other word line WL2 and the other capacitor contact region 5C form another transistor Tr2. The configuration is therefore such that the bit line contact region 5B is shared by the two transistors Tr1 and Tr2.

A bit line 20 extending in the X-direction is disposed on each bit line contact region 5B. A capacitor (which is not shown in the drawings) is disposed on each of the capacitor contact regions 5A and 5C. The transistor Tr1 and the transistor Tr2 form switching transistors of the DRAM memory cells.

Reference is now made to FIG. 1E. On a semiconductor substrate 1, word trenches 7B extending in a straight line in the Y-direction are provided straddling the first element isolation regions 2 and the active regions 5, comprising the semiconductor substrate 1, which are disposed repeatedly in the Y-direction. The word trenches 7B are formed from the first trenches 2b, provided at the intersections with the first element isolation regions 2, and the second trenches 10A, provided at the intersections with the active regions 5.

The second trenches 10A provided in the active regions 5 have, in a bottom portion thereof, a fin portion (protruding portion) 12 which protrudes upward from a bottom surface 12d in the shape of a fin. The fin portions 12 have two oblique side surfaces 12b and 12c which oppose one another in the Y-direction, and an upper surface 12a. Further, in the X′-direction, the oblique side surfaces 12b and 12c and the upper surface 12a impinge upon two side surfaces (12e and 12f illustrated in FIG. 1C and FIG. 1D, discussed hereinafter) which form the word trenches 7B and oppose one another in the X′-direction. The word lines WL1 and WL2 cover the fin portions 12 and are disposed extending in the Y-direction in lower portions (lower trenches) within the word trenches 7B.

The active regions 5 located on both sides of the word line WL1 in the X′-direction, sandwiching the word line WL1, form the capacitor contact regions 5A and the bit line contact regions 5B. Capacitor diffusion layers 6a are provided in upper portions within the capacitor contact regions 5A, and bit line diffusion layers 6bb are provided in upper portions within the bit line contact regions 5B. The capacitor diffusion layer 6a, the word line WL1 and the bit line diffusion layer 6bb form the transistor Tr1. The word line WL1 extending in the Y-direction functions as a gate electrode common to a plurality of transistors disposed along the word line WL1. Further, the fin portion 12 functions as the channel of the transistor.

Reference is now made to the cross-sectional view in FIG. 1A. The word lines WL1 and WL2 are each embedded, with the interposition of a gate insulating film 11, in a pair of second trenches 10A formed with the same width and spacing at the surface of the island-shaped active region 5 (semiconductor substrate 1) sandwiched between two second element isolation regions 3. Cap insulating films (second insulating films) 17 comprising a silicon nitride film are disposed filling an upper trench 16 located above each of the word lines WL1 and WL2.

The capacitor contact region 5A (see FIG. 1) adjacent to the word line WL1 forms a semiconductor pillar 5a demarcated on three sides by element isolation regions, and demarcated on the remaining one side by the second trench 10A. An n-type impurity diffusion layer is disposed in an upper portion of the semiconductor pillar 5a in such a way as to have an upper surface that coincides with an upper surface 1a of the semiconductor substrate 1, to form one of the capacitor diffusion layers (a first diffusion layer) 6a. Similarly, the capacitor contact region 5C (see FIG. 1) adjacent to the word line WL2 forms a semiconductor pillar 5c, and an n-type impurity diffusion layer is disposed in an upper portion of the semiconductor pillar 5c in such a way as to have an upper surface that coincides with the upper surface 1a of the semiconductor substrate 1, to form the other capacitor diffusion layer (third diffusion layer) 6c. Further, the bit line contact region 5B (see FIG. 1) sandwiched between the two word lines WL1 and WL2 forms a semiconductor pillar 5b, and an n-type impurity diffusion layer is disposed in an upper portion of the semiconductor pillar 5b in such a way as to have an upper surface that coincides with the upper surface 1a of the semiconductor substrate 1, to form the bit line diffusion layer (second diffusion layer) 6bb. The bottom surface of the bit line diffusion layer 6bb is coplanar with the bottom surfaces of the trenches 10A. The bottom surfaces of the trenches 10A are the same surface as the upper surface 12a of the fin portion 12.

A masking film (first interlayer insulating film) 8 comprising a silicon nitride film used as a mask for forming the word trench 7B is disposed on the upper surface 1a of the silicon substrate 1, and the upper surface of the masking film 8 and the upper surface of the cap insulating film 17 are coplanar.

A bit line contact plug (second contact plug) 19 which comprises an impurity-containing polycrystalline silicon film (DOPOS: Doped Poly-Silicon) and is connected to the upper surface of the bit line diffusion layer 6bb is disposed between the adjacent cap insulating films 17. The upper surface of the bit line contact plug 19 is coplanar with the upper surface of the cap insulating film 17.

The bit line 20 extending in the X-direction is disposed connected to the upper surface of the bit line contact plug 19. The bit line 20 is formed from metal, and contains at least tungsten. A cover insulating film 21 comprising a silicon nitride film is disposed covering the upper surface of the bit line 20. Side surface films 22 comprising silicon nitride films are disposed covering the side surfaces of the cover insulating film 21 and the bit line 20.

A second interlayer insulating film 23 comprising a silicon dioxide film is provided in such a way as to cover the cover insulating film 21, and the upper surface thereof is planarized. A first capacitor contact plug (first contact plug) 24a and a second capacitor contact plug (second contact plug) 24b are provided penetrating through the second interlayer insulating film 23 and the masking film 8 and connecting to the upper surfaces of the capacitor diffusion layers 6a and 6c respectively. Capacitor elements 25 are disposed connected to the upper surfaces of each of the capacitor contact plugs 24.

Reference is now made to FIG. 1C and FIG. 1D. FIG. 1C illustrates a cross section in the X′-direction, not passing through the fin portion 12. Further, FIG. 1D illustrates a cross section in the X-direction, passing through the fin portion 12. Therefore the bottom surface 12d of the fin portion 12 appears in FIG. 1C as the bottom surface of the second trench 10A, but in FIG. 1D the upper surface 12a of the fin portion 12 appears as the bottom surface of the second trench 10A. Other aspects of the configuration are the same. It should be noted that the configuration above the upper surface 1a of the semiconductor substrate 1 has been omitted. The reference codes 12a and 12d are sometimes used hereinafter to refer to the bottom surfaces of the second trench 10A.

The second trench 10A comprises the bottom surfaces 12a and 12d, and the two oblique side surfaces 12e and 12f which oppose one another in the X′-direction. A first insulating film 11A is disposed on the surfaces of the second trench 10A, in other words on the bottom surfaces 12a and 12d and the two oblique side surfaces 12e and 12f. A silicon oxide film (SiO) formed by thermal oxidation is used as the first insulating film 11A. The silicon oxide film is amorphous.

A barrier insulating film 11B is disposed on the surface of the first insulating film 11A. The barrier insulating film 11B can be formed using a single-layer film or a laminated film, comprising a silicon nitride film (SiN), a silicon oxynitride film (SiON), an aluminum nitride film (AlN) or an aluminum oxynitride film (AlON). All the abovementioned materials are amorphous. The barrier insulating film 11B can be formed to a thickness in a range of between 0.8 to 4.0 nm. The first insulating film 11A and the barrier insulating film 11B form the gate insulating film 11. In this embodiment, the gate insulating film 11 must be formed using the laminated film comprising the first insulating film 11A and the barrier insulating film 11B.

A barrier metal film 13, the outer surface (the bottom surface and the outside surfaces) of which has a U-shaped cross section, is disposed on surfaces 11ee and 11ff of the barrier insulating film 11B located in the lower trench within the second trench 10A. The barrier metal film 13 is formed from a titanium nitride (TiN) film, a tungsten nitride (WN) film or the like. A first recessed portion 13a is formed by disposing the barrier metal film 13.

A metal seed layer (seed layer) 14 having a U-shaped cross section is disposed with its outer surface in contact with the inner surface of the first recessed portion 13a. The metal seed layer 14 is formed from a tungsten (W) film. A second recessed portion 14a is formed by disposing the metal seed layer 14.

Further, a low-resistance metal film 15 is disposed in contact with the inner surface of the second recessed portion 14a and filling the second recessed portion 14a. The metal film 15 is formed from a W film. The barrier metal film 13, the metal seed layer 14 and the metal film 15 form the word line WL1. The word line WL1 is in contact with the gate insulating film 11, and the barrier insulating film 11B is disposed at the interface therebetween.

The abovementioned lower trench is defined as a part of the word trench 7B located lower than the bottom surface of the adjacent capacitor diffusion layer 6a.

As illustrated in FIG. 1C and FIG. 1D, the barrier metal film 13, the metal seed layer 14 and the metal film 15 respectively have upper surfaces 13b, 14b and 15b, and these upper surfaces are coplanar. Further, as illustrated in FIG. 1D, the bottom surface of the bit line diffusion layer 6bb is coplanar with the upper surface 12a of the fin portion 12. By this means, as illustrated by the dashed arrow Ch in FIG. 1D, the channel of the transistor Tr1 is formed in the vicinity of the surface of the semiconductor substrate 1, along the upper surface 12a of the fin portion 12 and the side surface 12e of the second trench 10A that is closer to the capacitor diffusion layer 6a.

A more detailed description will now be provided with reference to FIG. 1D. The description takes by way of example a case in which the minimum processing dimension F, which is the limit of resolution for lithography, is 25 nm. In the product generation in which F is 25 nm, the thickness of the gate insulating film 11 is 5 nm.

In this embodiment, as described in the method of manufacture discussed hereinafter, the first insulating film 11A and the barrier insulating film 11B are provided in such a way that the sum of their respective thicknesses TG1 and TG2 is maintained at 5 nm. Further, the opening width W1 of the second trench 10A, in the X-direction, after the barrier insulating film 11B has been disposed is 25 nm. The side surfaces of the second trench 10A are inclined, and therefore the width W2 of the upper surface of the word line WL1 embedded in the lower trench is 23 nm. In this embodiment, the barrier metal film 13 and the metal seed layer 14 can both be disposed with their respective thicknesses TB and TN reduced to 3 nm. However, at the stage at which the metal seed layer 14 having a U-shaped cross section is provided, it is possible to allow the second recessed portion 14a, the width TW of the centrally-located opening of which is 11 nm, to remain, making it possible to maintain a space in which to dispose the low-resistance metal film.

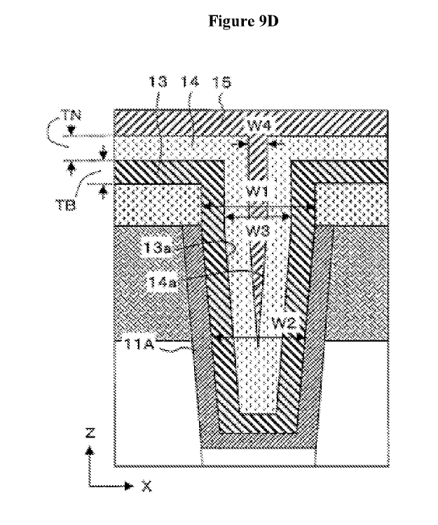

If the barrier insulating film 11B is not provided, as in the comparative example described with relation to embodiment 2 discussed hereinafter (see FIG. 9), the barrier properties deteriorate if the barrier metal film 13 and the metal seed layer 14 are made thinner, and degradation of the transistor characteristics appears, and therefore the respective thicknesses cannot be made thinner than 5 nm. There is thus a problem in that it is not possible to maintain a space in the lower trench in which to dispose the lower trench metal film 15. As a result, the resistance of the word line WL1 increases, and it is difficult to achieve a high-performance DRAM.

In this embodiment a configuration is adopted in which the barrier insulating film 11B, which has excellent barrier properties, is disposed within the gate insulating film 11, and therefore even if the metal film 15 is disposed in a condition in which the thickness of the barrier metal film 13 has been reduced to within a range of between 0.5 and 3 nm and the thickness of the metal seed layer 14 has been reduced to within a range of between 3 and 4 nm, the barrier properties as a whole can be maintained, and this has the advantage that it is possible for deterioration of the transistor to be avoided.

It should be noted that the depth H1 of the bottom surface 12d of the fin portion 12 from the upper surface 1a of the semiconductor substrate 1 can be shown by way of example as 180 nm. Further, the depth H2 of the upper surface 12a of the fin portion 12 can similarly be shown by way of example as 140 nm, and the depth H3 of the bottom surface of the capacitor diffusion layer 6a can be shown by way of example as 70 nm.

Reference is now made to FIG. 1B. FIG. 1B is a cross-sectional view through the line B-B′ in FIG. 1. The trapezoidal fin portion 12 is provided in the center of the active region 5 which is sandwiched between the first element isolation regions 2. The fin portion 12 comprises the bottom surface 12d, the upper surface 12a and the oblique side surfaces 12b and 12c which oppose one another in the Y-direction. The configuration of the fin portion 12 is such that the semiconductor substrate 1 protrudes out from the bottom surface 12d. The height H4 of the fin portion, defined between the bottom surface 12d and the upper surface portion 12a, is between 38 and 48 nm.

The gate insulating film 11 comprising the laminated film comprising the first insulating film 11A and the barrier insulating film 11B is disposed covering the abovementioned four surfaces. The barrier metal film 13, the metal seed layer 14 and the low-resistance metal film 15 are provided successively in such a way as to cover the surface of the gate insulating film 11, thereby forming the word line WL1. The word line WL1 extends in the Y-direction and fills the lower trench within the word trench 7B. The cap insulating film 17 which fills the upper trench 16 within the word trench 7B is disposed on the upper surface of the word line WL1. The word line WL2 is configured in the same way as the word line WL1.

It should be noted that the bottom surface 12d of the fin portion 12 does not necessarily need to be formed. As described in embodiment 2 discussed hereinafter, the fin portion may be one in which the oblique side surfaces 12b and 12c which oppose one another in the Y-direction protrude upward as a continuum from the side surfaces 2a of the first element isolation region.

According to the semiconductor device in this embodiment, the configuration comprises the trench provided in the semiconductor substrate, the insulating film (gate insulating film) covering the inner surfaces of the trench, and the embedded wiring line (word line) which fills the lower portion within the trench and is in contact with the insulating film, and the barrier insulating film is disposed at least at the interface between the insulating film and the embedded wiring line.

### Embodiment 2

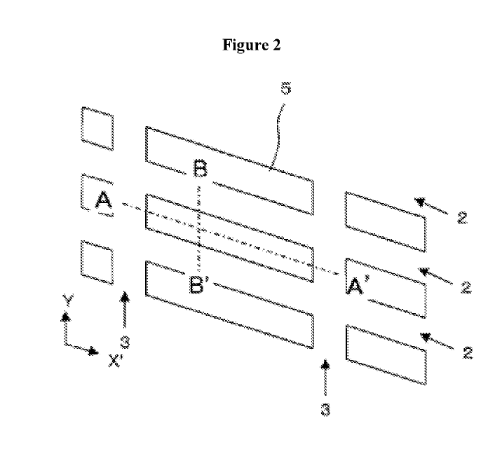

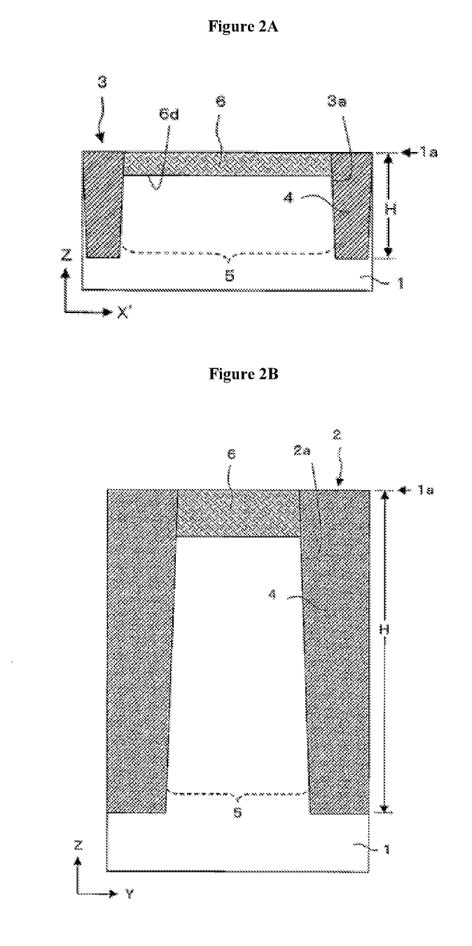

A method of manufacturing the semiconductor device discussed hereinabove will now be described with reference to FIG. 2 to FIG. 15A. Drawings having a drawing number without a letter appended thereto are plan views of each step. Further, drawings having a drawing number with the letter A appended are cross-sectional views through the line A-A′ illustrated in the corresponding plan view, or cross-sectional views in a location corresponding to the line A-A′, and drawings with the letter B appended are cross-sectional views through the line B-B′ illustrated in the corresponding plan view, or cross-sectional views in a location corresponding to the line B-B′.

Referring to FIG. 2, FIG. 2A and FIG. 2B, first a step of forming element isolation regions and active regions is implemented.

In a semiconductor substrate 1 comprising a p-type silicon single crystal, first element isolation grooves having side surfaces 2a and extending in the X′-direction (first direction), and second element isolation grooves having side surfaces 3a and extending in the Y-direction (second direction) are filled by element isolation insulating films 4, using a known STI (Shallow Trench Isolation) method.

A silicon dioxide film formed by CVD (Chemical Vapor Deposition) is used as the element isolation insulating film 4. There are thus formed a plurality of first element isolation regions 2 and a plurality of second element isolation regions 3, the depth H of which from the upper surface 1a of the semiconductor substrate 1 is 250 nm, for example. There are also formed a plurality of island-shaped active regions 5 which are demarcated in the X′-direction by the second element isolation regions 3 and in the Y-direction by the first element isolation regions 2.

n-type impurity diffusion layers 6 having an impurity concentration of 1E18 to 1E19 (atoms/cm³) are then formed at the surface of the active regions 5 using full-surface ion implantation. In a subsequent step, the n-type impurity diffusion layers 6 form capacitor diffusion layers 6a and 6c and part of a bit line diffusion layer 6bb. In this exemplary embodiment, the depth of the bottom surface 6d of the n-type impurity diffusion layer 6 is 70 nm.

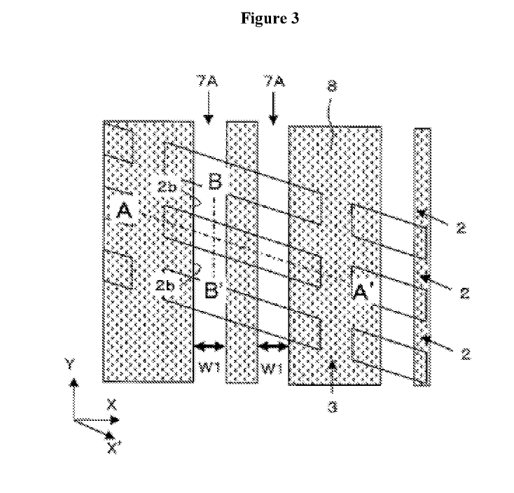

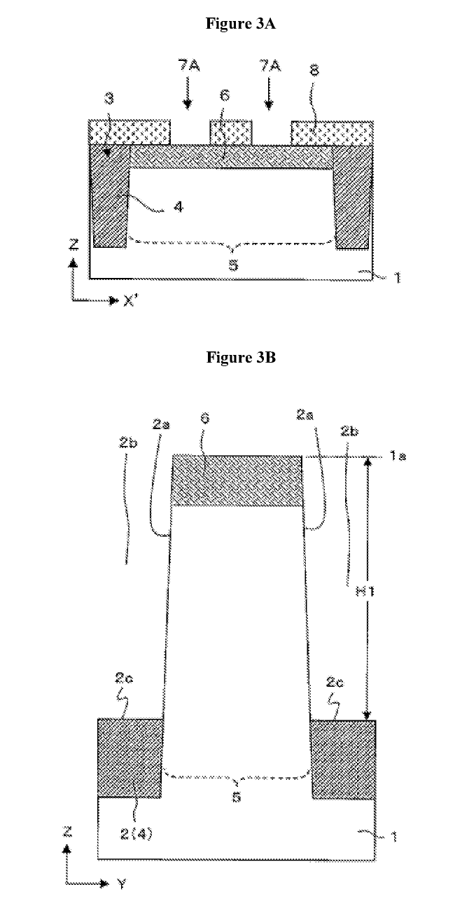

Referring to FIG. 3, FIG. 3A and FIG. 3B, next a step of forming first trenches, which are constituents of word trenches, is implemented.

A masking film 8 having word trench openings 7A which extend in the Y-direction and straddle a plurality of active regions 5 and first element isolation regions 2 is formed using known lithography and anisotropic dry etching methods. The masking film 8 functions later as a first interlayer insulating film. A silicon nitride film is used as the masking film 8. In one active region 5, two word trench openings 7A are formed in such a way as to be disposed uniformly in the X-direction. In this embodiment, the width W1 of the word trench openings 7A in the X-direction (third direction) is 25 nm. By this means, the upper surfaces of the active regions 5 and the upper surfaces of the first element isolation regions 2, disposed alternately, are exposed at the bottom surface of the word trench openings 7A which extend in the Y-direction.

The word trenches are next formed below the word trench openings 7A, but first, the first element isolation regions 2 are subjected to selective anisotropic dry etching using the masking film 8 as a mask. By this means the first element isolation regions 2 are etched to form first trenches 2b, as illustrated in FIG. 3B. The first trenches 2b comprise the side surfaces 2a of the first element isolation grooves and upper surfaces 2c of first element isolation insulating films 4. The depth H1 of the first trenches 2b from the upper surface la of the semiconductor substrate 1 is 180 nm.

Next, a step of forming second trenches, which are constituents of the word trenches, is implemented. In the step of forming the second trenches, a step of forming preliminary trenches is implemented before the second trenches 10A are formed.

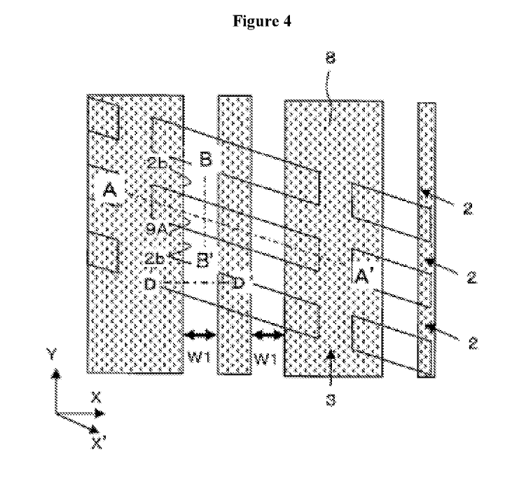

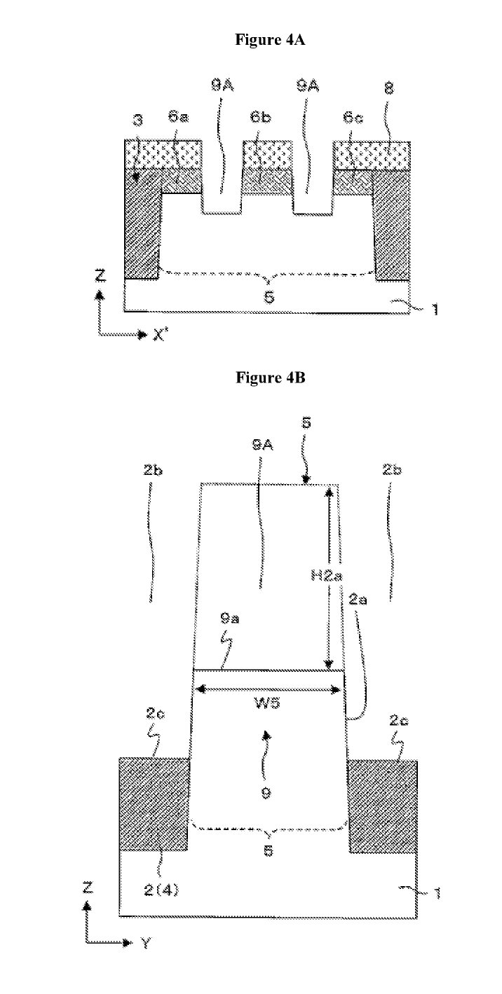

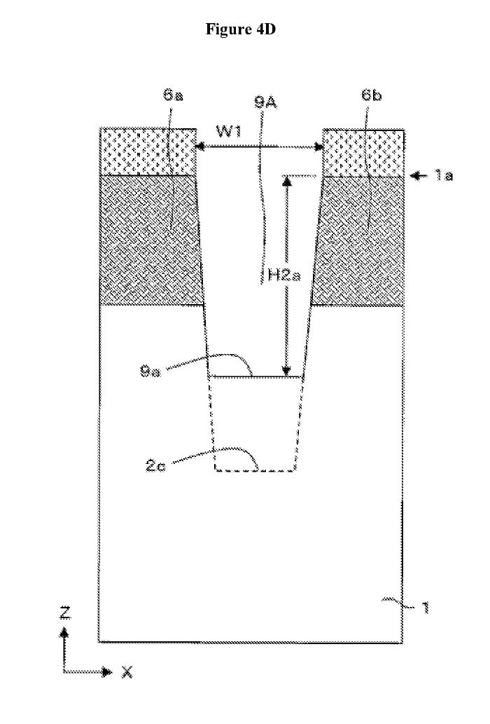

Referring to FIG. 4, FIG. 4A, FIG. 4B and FIG. 4D, the drawings illustrate the state after the step of forming the preliminary trenches by subjecting the active regions 5, the upper surfaces of which are exposed, to anisotropic dry etching using the masking film 8 as a mask. Thus, by adopting an etching depth H2a of 130 nm, for example, preliminary trenches 9A having upper surfaces 9a are formed. The width W5 of the upper surfaces 9a in the Y-direction is 28 nm. By forming the preliminary trenches 9A, preliminary fin portions 9, in which the active region 5 protrudes from the upper surface 2c of the first element isolation insulating film 4, are formed in the bottom portions of the preliminary trenches 9A. Further, by forming two preliminary trenches 9A in one active region 5, the n-type impurity diffusion layer 6 is divided into three parts, namely capacitor diffusion layers 6a and 6c and a bit line diffusion layer 6b.

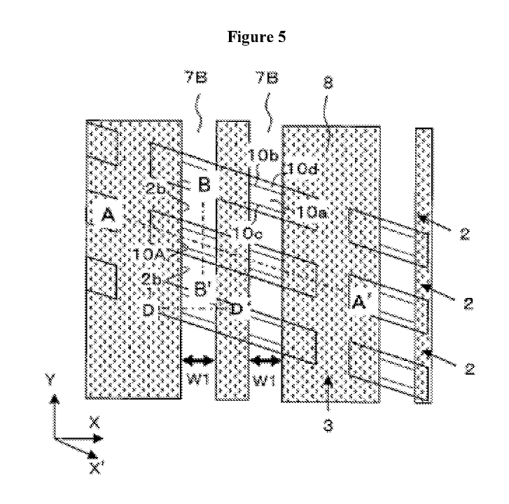

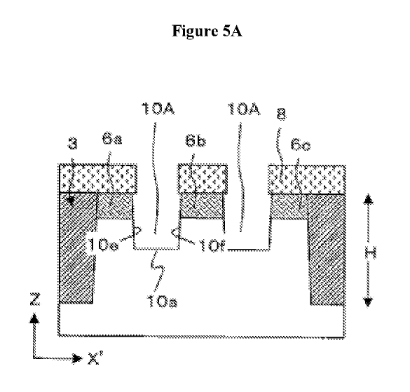

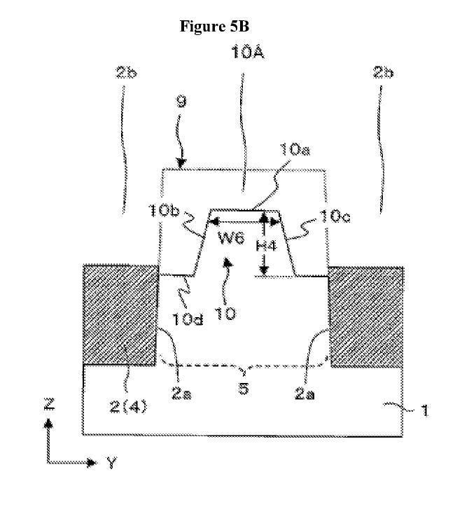

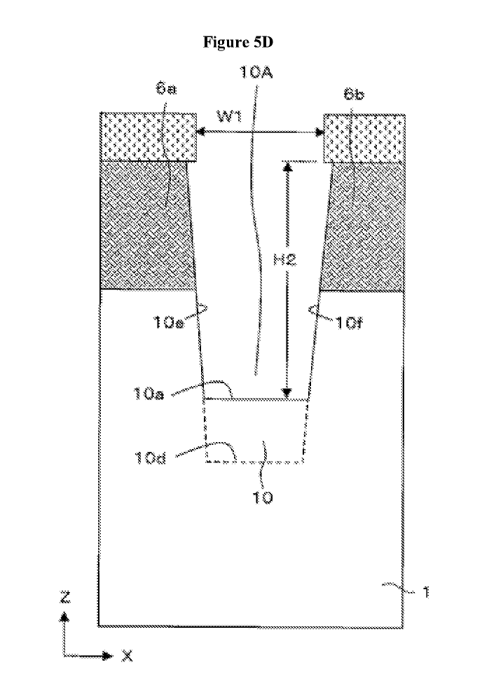

Referring to FIG. 5, FIG. 5A, FIG. 5B and FIG. 5D, following the step of forming the preliminary trenches 9A, next a step of forming second trenches 10A is implemented.

Dry etching conditions which allow both anisotropic etching and isotropic etching to be achieved are used in the formation of the second trenches 10A. Isotropic dry etching can be implemented by using conditions adjusted such that, compared with anisotropic dry etching, the pressure is increased and the bias power is decreased. In other words, the conditions should be controlled in a direction whereby the effect of the ions in the etching gas plasma is reduced. By this means, all the upper surfaces 9a and side surfaces 2a which form the preliminary fin portions 9 recede, to form the second trenches 10A having in a bottom portion thereof a fin portion 10 comprising new upper surfaces 10a, oblique side surfaces 10b and 10c which oppose one another in the Y-direction, and bottom surfaces 10d. By this means, the depth H2 of the upper surface 10a of the fin portion 10 becomes 140 nm, and the width W6 of the upper surface 10a in the Y-direction becomes 8 nm. It should be noted that the width W6 can be varied by adjusting the abovementioned etching conditions. Further, the fin portion is formed in such a way that its height H4 is between 38 and 48 nm. Word trenches 7B are thus formed, said word trenches 7B comprising the first trenches 2b formed in the first element isolation regions 2, and the second trenches 10A having side surfaces 10e and 10f which are formed in the active regions 5 and which oppose one another in the X′-direction.

It should be noted that in FIG. 5B the fin portion 10 is trapezoidal, but it is not limited to this shape. As miniaturization of semiconductor devices progresses, because the width W5 of the preliminary fin portion 9 in the Y-direction is itself small, the fin portion itself may in some cases cease to exist if excessive isotropic etching is implemented. Conditions that control the isotropic etching are used to avoid this. In this case fin portions 10 are formed, as illustrated in FIG. 5G and FIG. 5H, comprising only the side surfaces 10b and 10c, which extend upward as a continuum from the side surfaces 2a of the first element isolation regions 2, without the existence of the upper surface 10a and the bottom surface 10d. Even if fin portions 10 having such a shape are adopted, no problems whatsoever arise in terms of the transistor characteristics, and this embodiment is not impaired.

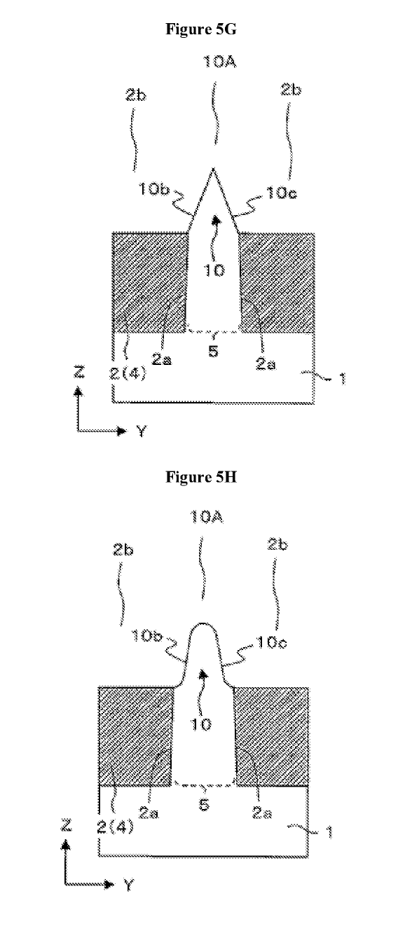

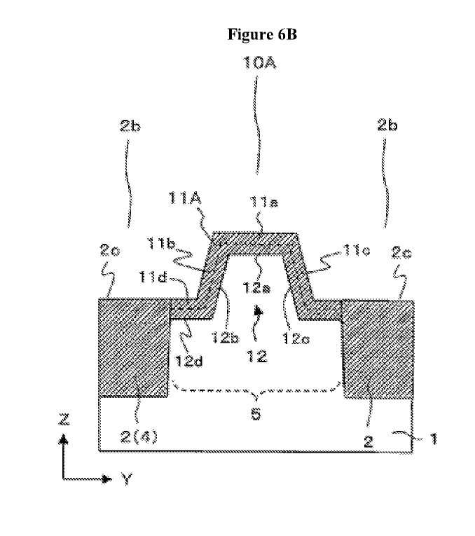

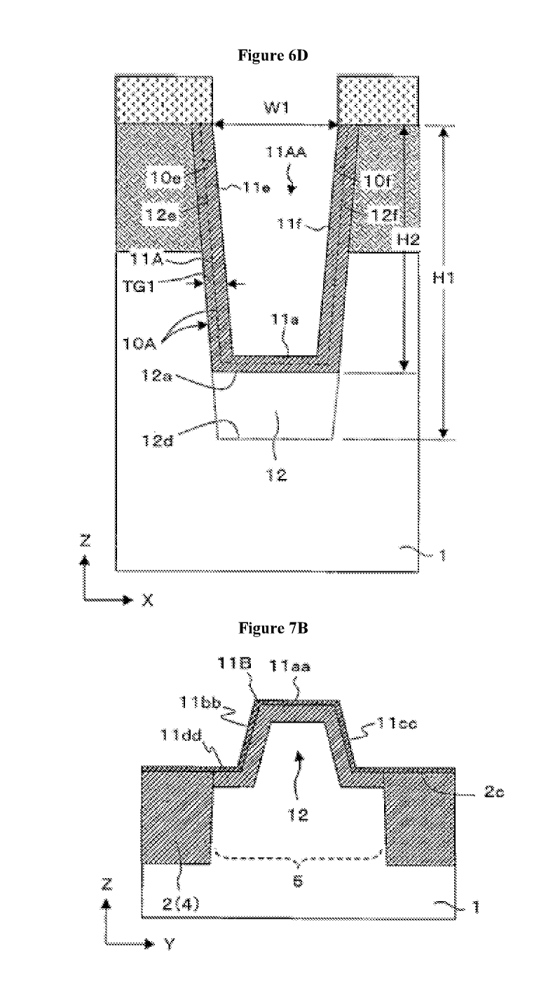

Referring to FIG. 6B and FIG. 6D, next a step of forming first insulating films on the inner surfaces of the second trenches 10A is implemented.

A first insulating film 11A comprising a silicon dioxide film having a thickness TG1 of 5 nm is formed using a known thermal oxidation method. It is known that the formation of a thermally-oxidized film has a mechanism whereby an oxidant diffuses through the silicon dioxide film being formed, and the oxidant which has reached the interface between the silicon and the silicon dioxide forms a new silicon dioxide film. Therefore if a silicon dioxide film having a thickness of 5 nm is formed, a 2.5 nm silicon dioxide film is formed on the inside of the original second trench 10A indicated by the dashed line, and a 2.5 nm silicon dioxide film is formed on the outside. By this means, as illustrated in FIG. 6D, a new second trench 10A (the line indicated by the arrow) comprising the semiconductor substrate 1 is formed in a position that has moved 2.5 nm inward from the original second trench 10A.

Further, in the stage in FIG. 5, the side surfaces 10e and 10f of the original second trench 10A are in a receded position relative to the edges of the masking film 8. Therefore, by forming the first insulating film 11A in this condition by thermal oxidation, silicon dioxide films 11e and 11f formed on the side surfaces 10e and 10f of the original second trench 10A are formed in such a way that the locations of the surfaces of said silicon dioxide films 11e and 11f are aligned with the edges of the masking film 8. In other words, the opening width of a third recessed portion 11AA formed by the first insulating film 11A is W1.

Referring to FIG. 6B, an upper surface silicon dioxide film 11a, side surface silicon dioxide films 11b and 11c, and a bottom surface silicon dioxide film 11d are formed in such a way as to cover the original fin portion 10, to form a new fin portion 12. The new fin portion 12 comprises an upper surface 12a, side surfaces 12b and 12c, and a bottom surface 12d.

In this embodiment, the first insulating film 11A is formed by thermal oxidation, and it is therefore only formed in the exposed parts of the silicon semiconductor substrate. There is no change in the shape of the masking film 8, and therefore the width W1 of the opening portion does not change. It should be noted that an O₂ atmosphere containing 20% H₂, at a temperature of 900° C., can be used as the conditions for forming the first insulating film 11A.

Referring to FIG. 7B and FIG. 7D, next a step of forming a barrier insulating film on the surface of the first insulating film 11A is implemented.

In this exemplary embodiment, a silicon nitride film formed by thermal nitriding is used as the barrier insulating film 11B. As methods for thermal nitriding, it is possible to employ simple heat treatment in which the heat treatment is performed in an ammonia (NH₃) atmosphere, or plasma-assisted heat treatment in which nitrogen radicals generated in a gas plasma serve as a nitriding material. Simple heat treatment is implemented at a temperature of between 600 and 800° C., and plasma-assisted heat treatment can be implemented at a temperature of between 50 and 500° C.

When thermal nitriding is used to form the barrier insulating film 11B on the surface of the first insulating film 11A comprising a silicon dioxide film, a nitriding agent diffusion process occurs in conjunction with a silicon dioxide film nitriding reaction. In other words, the barrier insulating film 11B is formed by replacing the first insulating film 11A with nitride. If there is excessive diffusion of nitriding agent that does not contribute to the nitriding reaction, nitrogen becomes trapped at the interfaces 12a, 12b, 12c and 12d between the first insulating film 11A and the semiconductor substrate 1, the interface state density increases, and there is a risk that the transistor characteristics may deteriorate. The thickness TG2 of the barrier insulating film 11B must therefore be less than the thickness TG1 of the first insulating film 11A.

In this embodiment, the thickness TG1 of the first insulating film 11A is 5 nm, and therefore the barrier insulating film 11B is formed in such a way that its thickness is in a range of between 0.8 and 4.0 nm. In order to control diffusion of the nitriding agent, heat treatment is preferably performed at a low temperature. From this viewpoint, it is more preferable to employ plasma-assisted heat treatment than simple heat treatment. In the plasma, a radical nitriding agent having an energy that is higher than that of atoms in the ground state is generated, and therefore the nitriding reaction can be promoted adequately even if the atmospheric temperature is low.

The thickness TG2 of the barrier insulating film 11B is preferably in a range of between 0.8 and 4.0 nm, and more preferably in a range of between 0.8 and 2.5 nm. If the thickness is less than 0.8 nm then the barrier effect is inadequate, and if it exceeds 4 nm, the increase in the interface state density discussed above causes the transistor characteristics to deteriorate.

It should be noted that the barrier insulating film 11B is formed by replacing the first insulating film 11A with nitride, and therefore if the barrier insulating film 11B having a thickness of 2 nm, for example, is formed on the surface of the first insulating film 11A, which has been formed to a thickness of 5 nm, then the thickness of the first insulating film 11A changes to 3 nm. However the total thickness of the first insulating film 11A and the barrier insulating film 11B does not change, remaining at 5 nm. Therefore the positional relationship between the edge of the masking film 8 and the third recessed portion 11AA formed by the barrier insulating film 11B does not change.

For the plasma feed gas it is preferable to use nitrogen (N₂), ammonia (NH₃) or hydrazine (N₂H₄). In a plasma, dissociation of gas molecules occurs concomitantly. Therefore a feed gas such as NF₃, for example, is not preferable as the dissociated fluorine (F) would etch the silicon dioxide film. Further, feed gases formed from C, N, H and Cl, such as organic amines, cause a carbon (C) film to be deposited, and are therefore not preferable.

The barrier insulating film 11B is formed from a silicon nitride film. More specifically, it is formed from either an SiN single-layer film, an SiON (silicon oxynitride film) single-layer film, a two-layer film in which an SiN film is formed on an SiON film, or a three-layer film comprising an SiON film/an SiN film/an SiON film. For the conditions for forming the barrier insulating film 11B it is possible to use a temperature of 500° C., with Ar and N₂ as the plasma feed gas, a pressure of 30 (Pa), and a microwave power of 1950 (W). Here, Ar does not contribute to the reaction, but is used as a plasma stabilizing gas.

The barrier insulating film 11B is formed through a thermal nitriding reaction, and it is therefore also formed on the surface 2c of the first element isolation insulating film 4, in addition to the surface of the first insulating film 11A formed from a silicon dioxide film. In other words, barrier insulating films 11ee, 11ff, 11aa, 11bb, 11cc and 11dd are formed respectively on the surfaces of the silicon dioxide films 11e and 11f formed on the side surfaces of the second trench 10A, the silicon dioxide films 11a, 11b, 11c and 11d formed on the upper surface, the side surfaces and the bottom surface of the fin portion 12, and the surface 2c of the first element isolation insulating film 4. Although not depicted in the drawings, the barrier insulating film 11B is also formed on the side surfaces of the first trench 2b. By forming the barrier insulating film 11B, the gate insulating film 11 comprising the first gate insulating film 11A and the barrier insulating film 11B is formed.

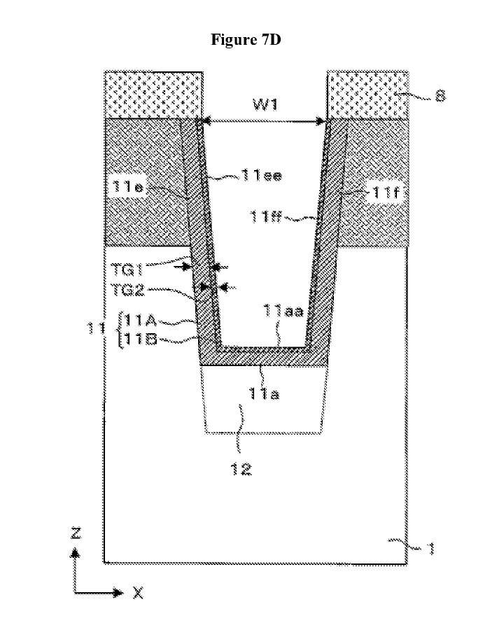

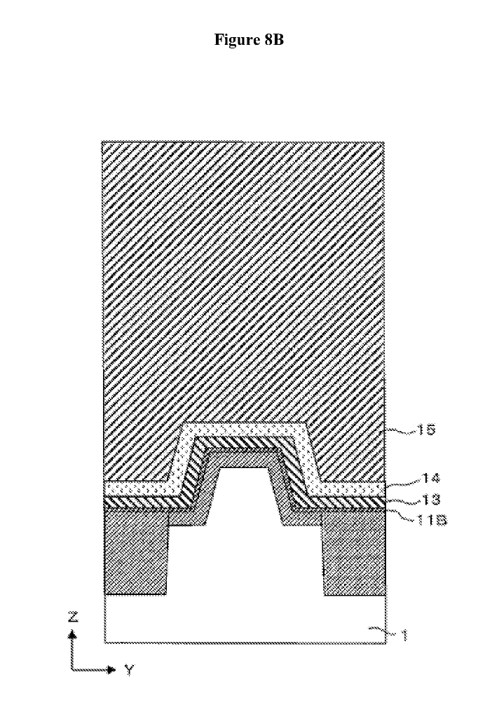

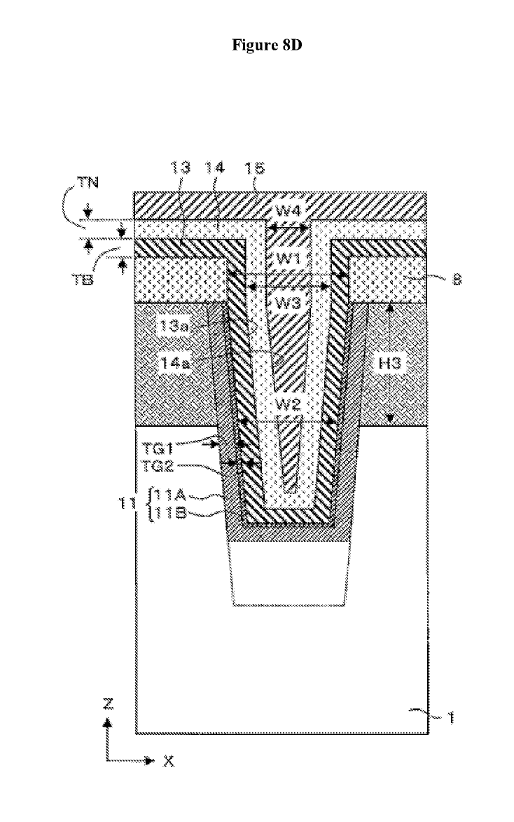

Reference is now made to FIG. 8B and FIG. 8D. A step of forming a barrier metal film on the barrier insulating film 11B is implemented.

The barrier metal film 13 can be formed to a reduced thickness TB in a range of between 0.5 and 3.0 nm, but here the thickness is set to 3 nm, for example. A titanium nitride (TiN) film or a tungsten nitride (WN) film can be used as the barrier metal film 13.

If the barrier metal film 13 is to be formed using a TiN film, sequential flow deposition (SFD), in which the film is formed using the following sequentially consecutive steps, can be used, for example. It should be noted that a common temperature of 650° C., for example, is used in all of the steps.

The following steps form one cycle, and the cycle is performed three times: 1. a TiN deposition step in which the pressure in the deposition chamber is maintained at 260 (Pa), for example, titanium tetrachloride (TiCl₄) serving as a feed gas, and NH₃ serving as a nitriding gas are supplied, and TiN is deposited on the barrier insulating film 11B,

2. a first purge step in which the supply of the feed gas and the nitriding gas is stopped, and N₂ purging is carried out while vacuum evacuation is being performed,
3. a nitride treatment step in which the pressure in the deposition chamber is maintained at 260 (Pa), NH₃ serving as a nitriding gas is supplied, and the TiN deposited in step 1 is further nitrided, and
4. a second purge step in which the supply of the nitriding gas is stopped, and N₂ purging is carried out while N₂ is being supplied.
By this means, the barrier metal film 13 having a thickness TB of 3 nm is formed.

Further, if the barrier metal film 13 is to be formed using a WN film, atomic layer deposition (ALD), in which the film is formed using the following sequentially consecutive steps, can be used, for example. It should be noted that in this case a common temperature of 380° C., for example, is used in all of the steps.

The following steps form one cycle, and the cycle is performed eight times: 1. a feed gas adsorption step in which the pressure in the deposition chamber is maintained at 260 (Pa), for example, tungsten hexafluoride (WF₆) serving as a feed gas is supplied, and the feed gas is adsorbed into the surface of the barrier insulating film 11B,

2. a first purge step in which the supply of the feed gas is stopped, and N₂ purging is carried out while vacuum evacuation is being performed,
3. a nitride treatment step in which the pressure in the deposition chamber is maintained at 260 (Pa), NH₃ serving as a nitriding gas is supplied, and the WF₆ adsorbed into the surface of the barrier insulating film 11B in step 1 is nitrided to form WN, and
4. a second purge step in which the supply of the nitriding gas is stopped, and N₂ purging is carried out while N₂ is being supplied.
By this means, the barrier metal film 13 having a thickness TB of 3 nm is formed.

As illustrated in FIG. 8D, at the stage at which the barrier metal film 13 having a thickness TB of 3 nm has been formed, a first recessed portion 13a, the width W3 of an opening portion of which, formed by the barrier metal film 13, is 19 nm, is formed within the third recessed portion 11AA, the width W1 of the opening portion of which in the X-direction is 25 nm. The first recessed portion 13a is formed as a recessed portion 13a extending in the Y-direction and straddling the first trench 2b and the second trench 10A.

Next a step of forming a metal seed layer on the barrier metal film 13 is implemented. In this embodiment, a low-resistance metal film to be formed on the metal seed layer 14 in the next step comprises tungsten, and therefore the metal seed layer 14 is formed from tungsten. In this embodiment, the metal seed layer 14 can be formed to a reduced thickness TN in a range of between 3.0 and 4.0 nm, but here the thickness is set to 3 nm, for example.

The metal seed layer 14 can, for example, be formed by ALD, in the same way as the method by which the barrier metal film 13 comprising the abovementioned WN film is formed. It is formed using the following sequentially consecutive steps. A common temperature of 350° C., for example, is used in all of the steps.

The following steps form one cycle, and the cycle is performed twelve times: 1. a feed gas adsorption step in which the pressure in the deposition chamber is maintained at 1000 (Pa), for example, WF₆ serving as a feed gas is supplied, and the feed gas is adsorbed into the surface of the barrier metal film 13,

2. a first purge step in which the supply of the feed gas is stopped, and N₂ purging is carried out while vacuum evacuation is being performed,
3. a reduction treatment step in which the pressure in the deposition chamber is maintained at 1000 (Pa), monosilane (SiH₄) serving as a reducing gas is supplied, and the WF₆ adsorbed into the surface of the barrier insulating film 11B in step 1 is reduced to form W seeds, and
4. a second purge step in which the supply of the reducing gas is stopped, and N₂ purging is carried out while N₂ is being supplied.
By this means, the metal seed layer 14 having a thickness TN of 3 nm is formed.

As illustrated in FIG. 8D, at the stage at which the metal seed layer 14 having a thickness TN of 3 nm has been formed, a second recessed portion 14a, the width W4 of an opening portion of which, formed by the metal seed layer 14, is 13 nm, is formed within the first recessed portion 13a, the width W3 of the opening portion of which in the X-direction is 19 nm. The second recessed portion 14a is formed as a recessed portion 14a extending in the Y-direction and straddling the first trench 2b and the second trench 10A.

Next a step of forming a metal film on the metal seed layer 14 is implemented.

The metal film 15 is formed from a low-resistance W film. The thickness of the metal film 15 is 40 nm. The metal film 15 can be formed, for example, by CVD, at a temperature of 390° C., a pressure of 10,000 (Pa), and using WF₆ as the feed gas and hydrogen (H₂) as the reducing gas.

As illustrated in FIG. 8D, at the stage at which the metal film 15 having a thickness of 40 nm has been formed, the second recessed portion 14a, the width W4 of the opening portion of which, formed by the metal seed layer 14, is 13 nm, is completely filled by the metal film 15. Further, because the width W4 of the opening portion formed by the metal seed layer 14 can be set to 13 nm, the low-resistance metal film 15 can be made to remain in the word line WL1 even at the stage at which the metal film 15, the metal seed layer 14 and the barrier metal film 13 have been etched back to form the embedded word line WL1, as discussed hereinbelow.

In contrast, FIG. 9D is a cross-sectional view in a case in which the barrier insulating film 11B is not formed, serving as a comparative example, at a time at which the barrier metal film 13 and the metal seed layer 14 have both been formed to the required thickness of 5 nm.

In the comparative example, at the stage at which the barrier metal film 13 having a thickness TB of 5 nm has been formed, the first recessed portion 13a, the width W3 of the opening portion of which, formed by the barrier metal film 13, is 15 nm, is formed within the second trench 10A, the width W1 of the opening portion of which in the X-direction is 25 nm. Further, at the stage at which the metal seed layer 14 having a thickness TN of 5 nm has been formed, the second recessed portion 14a, the remaining width W4 of the opening portion of which, formed by the metal seed layer 14, is only 5 nm, is formed within the first recessed portion 13a, the width W3 of the opening portion of which in the X-direction is 15 nm. The surface area occupied within the word line WL1 by the metal film 15 is thus very small, and it is difficult to form the low-resistance word line WL1. In particular, with semiconductor devices which have progressed to the F20 generation, W1 is 20 nm, and therefore the space in which to form the metal film 15 has itself already ceased to exist.

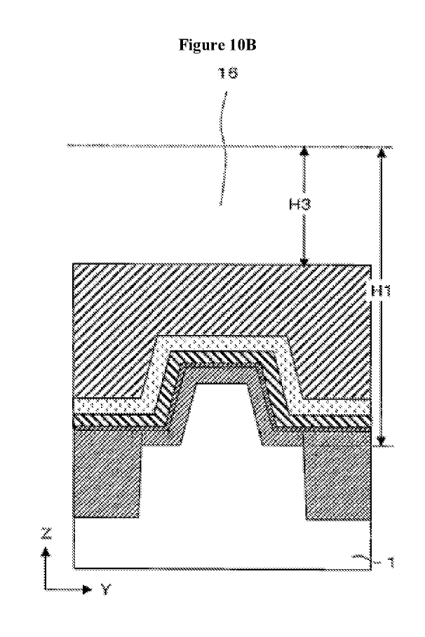

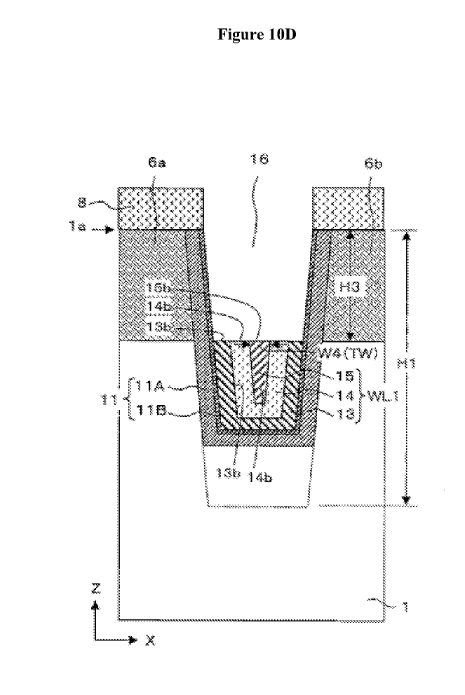

Reference is now made to FIG. 10B and FIG. 10D. After the metal film 15 has been formed, a step of forming the word line (embedded wiring line) WL1 is implemented.

Here, as a first stage, the metal film 15, the metal seed layer 14 and the barrier metal film 13 formed on the upper surface of the masking film 8 comprising a silicon nitride film are removed by CMP (Chemical Mechanical Polishing). The upper surface of the masking film 8 is thus exposed.

Next, as a second stage, the metal film 15, the metal seed layer 14 and the barrier metal film 13 remaining in the word trench 7B are etched back further by dry etching using a plasma containing sulfur hexafluoride (SF₆) and chlorine (Cl₂), with the masking film 8 as a mask. The word line WL1 filling the lower trench, which is a constituent of the word trench 7B, is thus formed.

The upper edge of the lower trench, in other words the upper surface of the word line WL1 formed by the upper surface 13b of the metal barrier film 13, the upper surface 14b of the metal seed layer 14 and the upper surface 15b of the metal film 15, said upper surfaces being coplanar, is coplanar with the bottom surface of the capacitor diffusion layer 6a. The depth H3 of the upper surface of the word line WL1 from the upper surface 1a of the semiconductor substrate 1 is 70 nm. By this means, an upper trench 16, which is a constituent of the word trench 7B, is formed directly above the word line WL1.

The side surfaces of the word trench 7B are inclined, and therefore the width of the upper surface of the word line WL1 is reduced to 90% of the width of the opening portion. However, at the stage in FIG. 8D, the width W4 of the opening portion of the second recessed portion 14a formed by the metal seed layer 14 is maintained at 13 nm, and therefore the width W4 in the X-direction of the upper surface of the word line WL1, in other words the width TW of the metal film 15, can be maintained at 12 nm.

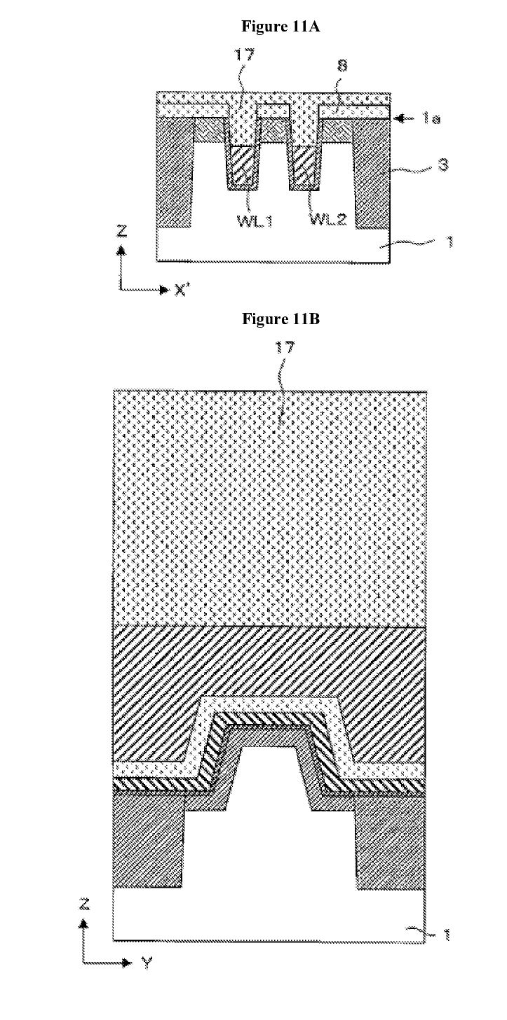

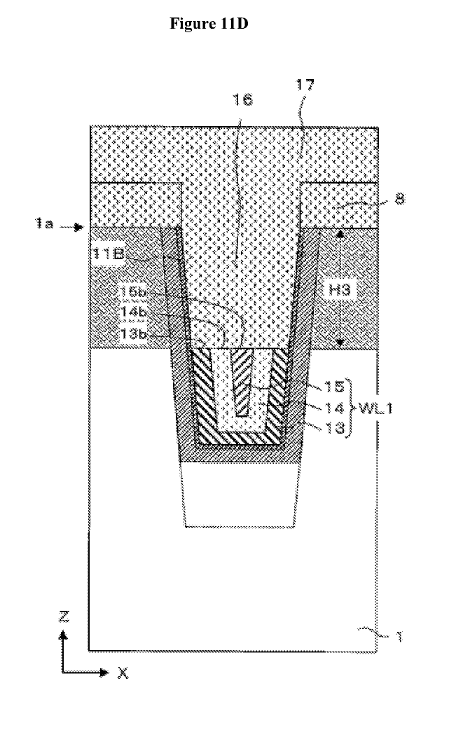

Reference is now made to FIG. 11A, FIG. 11B and FIG. 11D. After the word line WL1 has been formed, a step of forming a cap insulating film is implemented. A cap insulating film 17 comprising a silicon nitride film is formed by CVD in such a way as to fill the upper trench 16 that is formed directly above the word line WL1 by forming the word line WL1. The upper surface of the word line WL1 is thus covered by the cap insulating film 17. The cap insulating film 17 is formed in such a way that it also covers the upper surface of the masking film 8.

Next, as illustrated in FIG. 12A, after a masking film 18 having an opening for a bit contact region 5B has been formed, the cap insulating film 17 and the masking film 8 exposed in the opening are removed by anisotropic dry etching. A bit line contact hole 19a is thus formed, exposing the upper surface of part of the bit line diffusion layer 6b.

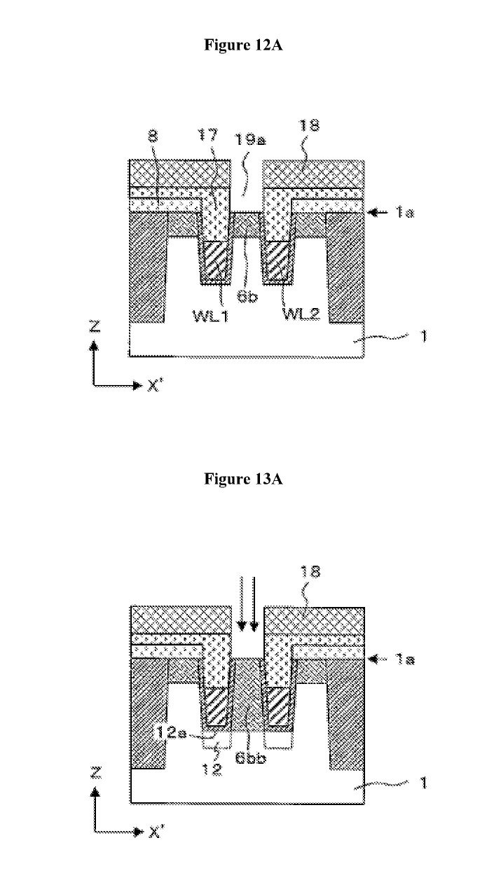

Next, as illustrated in FIG. 13A, phosphorus (P) and arsenic (As) are implanted into the bit line contact region by full-surface ion implantation, using the masking film 18 as a mask. Heat treatment is then performed at 800° C. to form the bit line diffusion layer 6bb. The bit line diffusion layer 6bb is formed in such a way that its bottom surface is coplanar with the upper surface 12a of the fin portion 12.

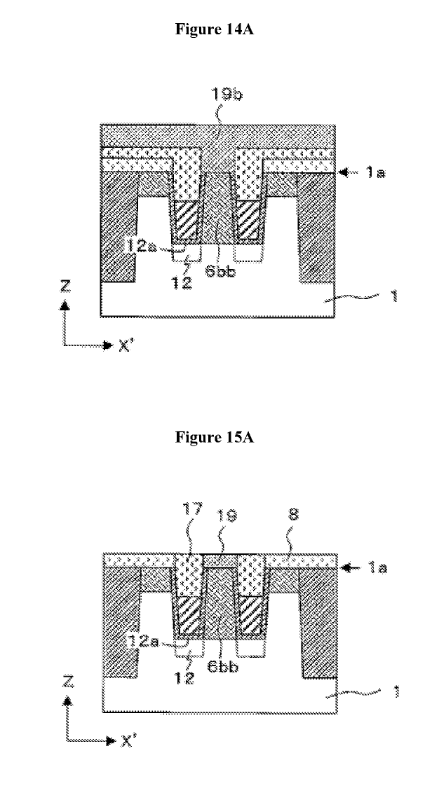

Next, as illustrated in FIG. 14A, after the masking film 18 has been removed, a silicon film 19b containing phosphorus is formed over the entire surface by CVD in such a way as to fill the bit line contact hole 19a.

Next, as illustrated in FIG. 15A, the entire surface of the silicon film 19b is etched back to form a bit line contact plug 19 in the bit line contact hole 19a. The cap insulating film 17 that was formed on the masking film 8 is also removed by this etching back. The upper surface of the masking film 8 is thus exposed.

Next, as illustrated in FIG. 1A, a metal film for bit lines and a cover insulating film are laminated over the entire surface. The cover insulating film and the bit line metal film are then etched successively by lithography and dry etching. By this means, bit lines 20, the upper surfaces of which are covered by the cover insulating film 21, and which extend in the X-direction, are formed as illustrated in FIG. 1. Side surface insulating films 22 covering the side surfaces of the cover insulating films 21 and the bit lines 20 are next formed. A second interlayer insulating film 23 is then formed over the entire surface. Capacitor contact plugs 24a and 24b which penetrate through the second interlayer insulating film 23 and the masking film 8 and connect to the capacitor diffusion layers 6a and 6c are then formed. Capacitor elements 25 connected to the upper surfaces of the capacitor contact plugs 24a and 24b are then formed. The semiconductor device in this embodiment can then be manufactured by forming an interlayer insulating film and upper layer wiring lines.

According to this embodiment, the embedded wiring lines (word lines) are formed in a state in which the barrier insulating film 11B, which has excellent barrier properties, has been formed in advance on the surface of the first insulating film 11A. Thus, even if the metal film 15 is formed in a state in which the thickness of the barrier metal film 13 has been reduced to within a range of between 0.5 and 3 nm, and the thickness of the metal seed layer 14 has been reduced to within a range of between 3 and 4 nm, the barrier properties as a whole can be maintained. In other words, even if the thickness of the barrier metal film or the seed layer which form the embedded wiring line is reduced, it is possible, by forming the barrier insulating film 11B in advance on the surface of the first insulating layer, to avoid the problem whereby reaction by-products generated when the metal film is formed diffuse into the insulating film, causing the reliability of the insulating film to deteriorate. It is thus possible to provide a semiconductor device comprising transistors having satisfactory characteristics, while at the same time preventing an increase in the resistance of the embedded wiring lines, even if the semiconductor device is miniaturized.

### Embodiment 3

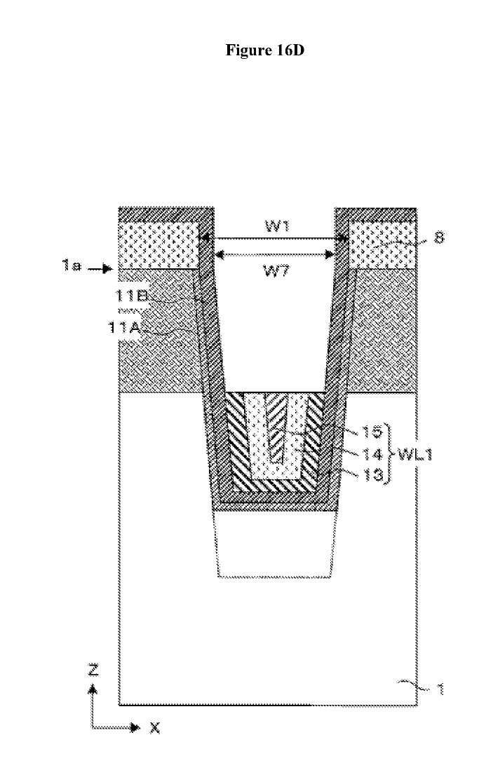

In embodiment 2 a method was described in which the barrier insulating film 11B is formed using thermal nitriding. In this embodiment 3, a method in which the barrier insulating film 11B having a thickness TG2 of 3 nm is formed by ALD, in other words by film deposition, is described with reference to FIG. 16D.

In the same way as in FIG. 5 in embodiment 2, the word trench 7B (10A) is formed using as a mask the masking film 8 which has an opening width W1 of 25 nm. Then, as illustrated in FIG. 16D, the first insulating film 11A having a thickness TG1 of 2 nm is formed by the same thermal oxidation method as in embodiment 2. The barrier insulating film 11B having a thickness TG2 of 3 nm is then formed by ALD.

A silicon nitride film (SiN), a silicon oxynitride film (SiON), an aluminum nitride film (AlN), an aluminum oxynitride film (AlON) or the like can be used as the barrier insulating film 11B formed by ALD. Each of these is an amorphous crystalline film. Further, in addition to being formed as single-layer films, said films may also be formed as laminated films.

If an SiN film or an SiON film is to be formed by ALD, plasma-assisted ALD is used. With plasma-assisted ALD, deposition is implemented by causing a feed gas and a nitriding gas to enter a plasma state and supplying the same to a deposition chamber, or by plasmatizing gas that has been supplied to a deposition chamber. Silicon radicals and nitrogen radicals thus serve as reactants, and therefore deposition can be implemented at a lower temperature, even if a thermal reaction alone would not cause the gas to react.

For example, if an SiON film is to be formed by plasma-assisted ALD, the film can be formed using the following sequentially consecutive steps. All the steps can be implemented at a temperature in a range of between 450 and 550° C., but here a common temperature of 500° C. is used by way of example.

The following steps form one cycle, and the cycle is performed six times: 1. a nitriding gas adsorption step in which the pressure in the deposition chamber is maintained at 100 (Pa), for example, NH₃ serving as a nitriding gas is plasmatized to supply N radicals, and atomic layer nitrogen is adsorbed into the surface of the first insulating film 11A,

2. a first purge step in which the supply of the nitriding gas is stopped, and N₂ purging is carried out while vacuum evacuation is being performed,
3. a first deposition step in which the pressure in the deposition chamber is maintained at 100 (Pa), dichlorosilane (SiH₂Cl₂) serving as a feed gas is plasmatized to supply Si radicals, and the N adsorbed into the surface of the first insulating film 11A in step 1 reacts with the Si radicals to form SiN,
4. a second purge step in which the supply of the feed gas is stopped, and N₂ purging is carried out while vacuum evacuation is being performed,
5. a second deposition step in which the pressure in the deposition chamber is maintained at 100 (Pa), ozone (O₃) serving as an oxidizing gas is supplied, and the SiN formed in step 3 is oxidized to form SiON, and
6. a third purge step in which the supply of the oxidizing gas is stopped, and N₂ purging is carried out while vacuum evacuation is being performed.
By this means, the barrier insulating film 11B having a thickness TG2 of 3 nm is formed. Here, SiH₂Cl₂ is used as the feed gas, and NH₃ is used as the nitriding gas, but these may respectively be monosilane (SiH₄) and N₂. With organic feed gases, the plasma causes a carbon film to be deposited, and these are therefore not preferable. It should be noted that if an SiN film is to be deposited, steps 5 and 6 should not be implemented.

Further, if an AlON film is to be formed by plasma-assisted ALD, the film can be formed using the following sequentially consecutive steps. All the steps can be implemented at a temperature in a range of between 300 and 450° C., but here a common temperature of 400° C. is used by way of example.

The following steps form one cycle, and the cycle is performed six times: 1. a feed gas adsorption step in which the pressure in the deposition chamber is maintained at 100 (Pa), trimethyl aluminum (TMA: Al(CH₃)₃) serving as a feed gas is supplied, and the TMA is adsorbed into the surface of the first insulating film 11A,

2. a first purge step in which the supply of the feed gas is stopped, and N₂ purging is carried out while vacuum evacuation is being performed,
3. a first deposition step in which the pressure in the deposition chamber is maintained at 100 (Pa), ozone (O₃) serving as an oxidizing gas is supplied, and the TMA adsorbed into the surface of the first insulating film 11A in step 1 is oxidized to form AlO,
4. a second purge step in which the supply of the oxidizing gas is stopped, and N₂ purging is carried out while vacuum evacuation is being performed,
5. a second deposition step in which the pressure in the deposition chamber is maintained at 100 (Pa), for example, NH₃ serving as a nitriding gas is plasmatized to supply N radicals, and the AlO formed in step 3 is nitrided to form AlON, and
6. a third purge step in which the supply of the nitriding gas is stopped, and N₂ purging is carried out while vacuum evacuation is being performed.
By this means, the barrier insulating film 11B having a thickness TG2 of 3 nm is formed. Here, NH₃ is used as the nitriding gas, but N₂ may also be used. It should be noted that if an MN film is to be deposited, steps 3 and 4 should not be implemented.

As illustrated in FIG. 16D, by forming the barrier insulating film 11B using ALD, the barrier insulating film 11B is formed not only on the first insulating film 11A formed in the word trench 7B, but over the entire surface including the masking film 8. At this stage, the opening width W1 of the masking film 8 in the X-direction that was 25 nm has been reduced to an opening width W7 of 19 nm.

Next, the barrier metal film 13 having a thickness of 0.5 nm is formed in the same way as in embodiment 2. If the barrier insulating film 11B, which has excellent barrier properties, is formed to a thickness of 2.5 nm or more then it is not necessary to form the barrier metal film, but there is a risk that the metal film including the seed metal layer formed later may peel off the insulating film. The barrier metal film 13 is formed as an adhesive layer to prevent this. In this case it is not necessary for the barrier metal film 13 to be a TiN film, and it may be formed using sputtering, which has excellent adhesion.

The metal seed layer 14 having a thickness of 3 nm, comprising W, and the metal film 15 comprising W having a thickness of 40 nm are then deposited successively in the same way as in FIGS. 8B and C in embodiment 2. Etching is also performed in the same way as in FIGS. 10B and C. The DRAM is subsequently manufactured in the same way as in embodiment 2.

In this embodiment the barrier insulating film 11B having a thickness of 3 nm is formed by ALD, instead of by the thermal nitriding method described in embodiment 2. Thermal nitriding has the drawback that a long deposition time is required to form the barrier insulating film 11B to a thickness greater than 2 nm, but this drawback can be overcome by using ALD. It is also effective to implement a combination of the two methods, for example forming the first 1 nm using the thermal nitriding method in embodiment 2, and forming the remaining 2 nm using the ALD method in this embodiment.

According to this embodiment, the metal barrier film 13 having a thickness of 0.5 nm and the metal seed layer 14 having a thickness of 3 nm are formed in the opening having a width W7 of 19 nm. Therefore the opening width before formation of the metal film 15 is 12 nm, and sufficient space can be maintained in the word trench 7B in which to form the metal film 15. If a combination of the two methods described above is used to form the film, the thickness of the part of the barrier insulating film 11B formed by ALD can be reduced further, and space can be maintained to form an even larger metal film. For example, if 2 nm of the barrier insulating film 11B is formed by thermal nitriding, and 2 nm is formed by ALD, the width of the opening W7 is 21 nm. If the barrier metal film 13 is formed to a thickness of 0.5 nm and the metal seed layer 14 is formed to a thickness of 3 nm, then the opening width prior to formation of the metal film is 14 nm. Even if miniaturization progresses to the F20 generation, a 9 nm opening width can be ensured, and the low-resistance metal film 15 can be formed as the word line.

Several modes of embodiment of the present invention have been described hereinabove, but various variations and modifications may be made within the scope of the present invention, without limitation to the abovementioned modes of embodiment of the present invention. The deposition methods, deposition conditions, etching methods, etching conditions, film thicknesses and the like in the abovementioned modes of embodiment are merely shown by way of example.

This application is based upon and claims the benefit of priority from Japanese Patent Application No. 2012-250106, filed on Nov. 14, 2012, the entire disclosure of which is incorporated herein by reference.

### Explanation of the Reference Numbers

1 Semiconductor substrate
1a Upper surface
2 First element isolation region
2a Side surface
2b First trench
2c Upper surface
3 Second element isolation region
3a Side surface
4 Element isolation insulating film
5 Active region
5a, 5b, 5c Semiconductor pillar
5A, 5C Capacitor contact region
5B Bit line contact region
6 n-type impurity diffusion layer
6a, 6c Capacitor diffusion layer
6b Bit line diffusion layer
6bb Bit line diffusion layer
6d Bottom surface
7A Word trench opening
7B Word trench
8 Masking film
9 Preliminary fin portion
9a Upper surface
9A Preliminary trench
10 Fin portion
10a Upper surface
10b, 10c Oblique side surface
10e, 10f Side surface
10d Bottom surface
10A Second trench
11 Gate insulating film
11a Upper surface silicon dioxide film
11b, 11c Side surface silicon dioxide film
11d Bottom surface silicon dioxide film
11e, 11f Silicon dioxide film
11aa, 11bb, 11cc, 11dd Barrier insulating film
11ee, 11ff Obverse surface
11A First insulating film
11AA Third recessed portion
11B Barrier insulating film
12 Fin portion
12a Upper surface
12b, 12c Oblique side surface
12d Bottom surface
12e, 12f Side surface
13 Barrier metal film
13a First recessed portion
13b Upper surface
14 Metal seed layer
14a Second recessed portion
14b Upper surface
15 Metal film
15b Upper surface
16 Upper trench
17 Cap insulating film
18 Mask
19 Bit line contact plug
19a Bit line contact hole
19b Silicon film
20 Bit line
21 Cover insulating film
22 Side surface insulating film
23 Second interlayer insulating film
24a First capacitor contact plug
24b Second capacitor contact plug
25 Capacitor element
100 Memory cell region

1. A semiconductor device comprising:
a trench provided in a semiconductor substrate;
an insulating film covering an inner surface of the trench; and
an embedded wiring line which fills a lower portion within the trench and which is in contact with the insulating film,
wherein a barrier insulating film is disposed at least at an interface between the insulating film and the embedded wiring line.

2. The semiconductor device of claim 1, wherein the embedded wiring line comprises:
a concave barrier metal film, an outer surface of which is in contact with the insulating film;
a concave seed layer, an outer surface of which is in contact with an inner surface of the concave barrier metal film; and
a metal film which fills the recessed portion of the concave seed layer.

3. The semiconductor device of claim 1, wherein the barrier insulating film is a film containing nitrogen.

4. The semiconductor device of claim 3, wherein the barrier insulating film is a laminated film comprising one or more films selected from a silicon nitride film, a silicon oxynitride film, an aluminum nitride film, and an aluminum oxynitride film.

5. The semiconductor device of claim 3, wherein the barrier insulating film is a film formed by nitriding part of the insulating film.

6. The semiconductor device of claim 3, wherein the barrier insulating film is a film formed in such a way as to cover an inner surface of a first insulating film which forms part of the insulating film.

7. The semiconductor device of claim 1, wherein the insulating film forms a gate insulating film of a transistor.

8. The semiconductor device of claim 7, wherein the trench has a fin portion in a bottom portion thereof, and the gate insulating film covers at least the entire surface of the fin portion.

9. The semiconductor device of claim 8, comprising:
a first diffusion layer disposed on one side surface of the trench;
a second diffusion layer disposed on another side surface facing said one side surface; and
a bottom surface of the second diffusion layer coplanar with an upper surface of the fin portion.

10. The semiconductor device of claim 7, wherein the first insulating film forming part of the insulating film is a film formed by thermally oxidizing the inner surface of the trench.

11. The semiconductor device of claim 10, wherein the semiconductor substrate is a silicon substrate, and the first insulating film is a silicon dioxide film.

12. The semiconductor device of claim 7, wherein the transistor is a cell transistor of a memory cell.

13. The semiconductor device of claim 1, wherein the thickness of the barrier insulating film is in a range of between 0.8 and 4.0 nm.

14. A method of manufacturing a semiconductor device, comprising:
forming a trench in a semiconductor substrate;
forming a first insulating film on an inner surface of the trench;
forming a barrier insulating film at least on the first insulating film;
forming a barrier metal film over the entire surface including the barrier insulating film;
forming a seed layer on the barrier metal film;
filling the trench by forming a metal film on the seed layer; and
etching back the metal film, the seed layer and the barrier metal film to form an embedded wiring line filling a lower portion of the trench.

15. The method of claim 14, wherein forming the barrier insulating film comprises nitriding part of the obverse surface side of the first insulating film.

16. The method of claim 15, wherein forming the first insulating film on the inner surface of the trench comprises oxidizing the inner surface of the trench by thermal oxidation, and wherein nitriding part of the obverse surface side of the first insulating film comprises replacing oxygen in the first insulating film with nitrogen.

17. The method of claim 15, wherein nitriding part of the obverse surface side of the first insulating film comprises employing thermal nitriding.

18. The method of claim 15, wherein nitriding part of the obverse surface side of the first insulating film comprises employing plasma nitriding.

19. The method of claim 14, wherein forming the barrier insulating film comprises forming a laminated film comprising one or more films selected from a silicon nitride film, a silicon oxynitride film, an aluminum nitride film, and an aluminum oxynitride film.

20. The method of claim 19, wherein forming the barrier insulating film comprises employing atomic layer deposition (“ALD”).

21. The method of claim 14, wherein forming the barrier insulating film is performed in such a way that the thickness of the barrier insulating film is in a range of between 0.8 and 4.0 nm.

22. The method of claim 14, comprising forming a transistor in which the first insulating film and the barrier insulating film serve as a gate insulating film.

23. The method of claim 22, comprising forming a storage element connected to the transistor.
